(19) United States
(12) Patent Application Publication
(10) Pub. No.: US 2014/0009176 A1
(43) Pub. Date: Jan. 9, 2014

(54) CAPACITANCE MEASUREMENT CIRCUIT

(71) Applicant: APPLE INC., Cupertino, CA (US)

(72) Inventors: Saman Saeedi, Pasadena, CA (US); Shafiq M. Jamal, Pleasanton, CA (US); Ahmad AI-Dahle, Santa Clare, CA (US)

(73) Assignee: Apple Inc., Cupertino, CA (US)

(21) Appl. No.: 13/691,285

(22) Filed: Nov. 30, 2012

Related U.S. Application Data
(60) Provisional application No. 61/668,892, filed on Jul. 6, 2012.

(51) Int. Cl. G01R 27/26

(52) U.S. Cl. CPC G01R 27/2605
USPC 324/681

(57) ABSTRACT

A resistor having a known resistance is coupled in series with a device under test (DUT) having an unknown capacitance. An ac signal source having a known fundamental frequency is coupled to drive the resistor to thereby produce a first ac signal. A phase controllable signal generator produces a second ac signal. The first and second ac signals are fed to a mixer. An output of the mixer is low pass filtered. A peak detector monitors the low pass filtered output while sweeping the phase controllable signal generator, until a peak is detected. The set phase corresponding to the detected peak is then used to obtain an estimate of the unknown DUT capacitance. Other embodiments are also described and claimed.

### RELATED MATTERS

This application claims the benefit of the earlier filing date of provisional application No. 61/668,892, filed Jul. 6, 2012, entitled “Capacitance Measurement Circuit”.

### FIELD

An embodiment of the invention relates to techniques for automated measurement of relatively small capacitance such as the parasitic gate-drain capacitance in thin film transistors. Other embodiments are also described.

### BACKGROUND

Flat panel displays such as liquid crystal display (LCD), plasma, and organic light emitting diode (OLED) types are typically used in consumer electronics devices, such as desktop computers, television sets, and portable devices such as smart phones, tablet computers, and notebook computers. A flat panel display contains an array of display elements, where each element receives a signal that represents a digital picture element to be displayed at that location. In active matrix displays, the picture element signal is delivered as a data line signal that is applied to a carrier electrode of a thin film transistor (TFT) that is part of the display element (also referred to as a pixel TFT). Another carrier electrode of the transistor is connected to a charge storage circuit within the display element, such as a liquid crystal capacitor. A select signal at the control electrode of the transistor, also referred to as a gate line signal, modulates or turns on or off the TFT, so as to apply the data line signal to the charge storage circuit in order to produce an analog pixel signal across the liquid crystal capacitor, to thereby control the contribution of that display element to the overall display image. Thousands or millions of copies of such display elements are reproduced in the form of an array, and in the case of LCD panels on a transparent substrate, such as a plane of glass or plastic. This array is overlaid with a grid of conductive data lines and gate lines, where each data line delivers the picture element signals to the source electrodes of the TFTs in a column, while the drain electrode of each TFT is connected to its associated liquid crystal storage cell, and each of the gate lines serves to apply a scanning-type select signal to the gate electrodes of a row of TFTs.

The display elements and the grid of data lines and gate lines, together with their associated gate line and data line driver circuitry, are typically formed using microelectronic semiconductor processing techniques directly on the transparent substrate. However, microelectronics formed on a glass substrate do not behave the same as those formed on a semiconductor substrate such as silicon. The TFTs on glass have inconsistent performance and are likely to degrade quickly over time and with use. As a result, the quality, accuracy and appearance of such a display panel may change as the behavior of its constituent TFTs changes.

### SUMMARY

The degradation of a TFT can result in slow and inconsistent response times by the TFT, such as when a TFT in a display element is responding to its gate line driver signal. It has been found, for example, that the gate line drive voltage may need to be increased in order to obtain the same response, as the TFT degrades due to an increase in its parasitic gate drain capacitance, referred to here as C_{gd}. In particular, the degradation in C_{gd} slows the reaction time of the TFT, particularly when the transistor is being switched off. Better performance could be obtained by monitoring or tracking an estimate of C_{gd} that is representative of the TFTs used in the active region of the display panel, as the display system is being used during its normal life cycle, and then adjusting, for example, the gate line drive signals so as to compensate for expected changes or degradation in the C_{gd} of the active area TFTs.

An embodiment of the invention is a technique for automatically measuring a relatively small capacitance (such as found in the C_{gd} of a TFT). The measurement is made using a measurement or test circuit that may be integrated with the display system, so as to allow the monitoring of a degrading capacitance over the life cycle of the display system. While the techniques described here may also be used to obtain a measure or an estimate of capacitance in any device under test (DUT), they are particularly suitable for integration into a display system, to measure C_{gd} of a TFT. For greater accuracy, the measurement circuit may be implemented on a silicon microelectronics substrate separate from the display panel substrate (e.g., glass substrate) on which the TFT under test is actually present, using a mature digital microelectronics fabrication process such as a complimentary metal oxide semiconductor (CMOS) process.

In one embodiment, the measurement circuit has a resistor having a known resistance, and that is to be coupled in series with the DUT having an unknown capacitance. An ac signal source having a known fundamental frequency is coupled to drive the resistor, to thereby produce a first ac signal at the resistor. A phase controllable signal generator is provided, that produces a second ac signal. In one embodiment, the second ac signal has a known fundamental frequency that may be about the same as that of the first ac signal, and also has a known phase relative to that of the ac signal source. The first and second ac signals are then fed to respective inputs of a mixer. An output of the mixer is then low-pass filtered, and is monitored by a peak detector. The peak detector has an output that is coupled to control the variable phase of the second ac signal, through the phase controllable signal generator.

The phase shift produced by the signal generator is swept, while the peak detector monitors the low pass filter output, until a maximum or peak is detected. The set phase value that produces the peak is referred to as φₘₐₓ—this value, which may be provided at the output of the peak detector, is then used to obtain a measure of the unknown capacitance of the DUT. For instance, φₘₐₓ can be used to access a previously determined lookup table, to thereby read out a corresponding capacitance value. The lookup table may have been determined using a mathematical relationship that gives capacitance as a function of several variables including φₘₐₓ, the resistance of the resistor, and the fundamental frequency. As an alternative to the lookup table, the estimated DUT capacitance can be computed directly using the mathematical relationship.

In one embodiment, the ac signal source contains a square wave generator having an output that feeds a band pass filter through a frequency divider. This arrangement avoids the need for analog circuitry to directly produce the first ac signal, which may be a narrowband or single tone (or essentially a single sinusoid) voltage source signal. To further take advantage of the mature circuit elements available with typical large scale integration digital microelectronic fabrication processes, the phase controllable signal generator may be implemented using a digital phase shifter. The phase shifter may have a first control input coupled to an output of the square wave generator to receive a high frequency step or resolution signal, a second control input that is coupled to the output of the peak detector, and a signal input that is coupled to an output of the frequency divider. Such an implementation makes good use of circuit elements that are readily available in standard digital microelectronics fabrication processes.

Some additional benefits of using the above-described techniques for capacitance measurement may include improved accuracy in the measurement or estimation of relatively small capacitance values (e.g., such as the C_{gd} of thin film transistors), reduced chip real estate or area overhead, and increased immunity to measurement errors and offset or mismatch errors. The latter benefit may be especially due to the use of the peak detector while sweeping the set phase of the phase controllable signal generator, to the find the set phase value (φₘₐₓ) that yields a peak or maximum in the low pass filtered signal, and then using the mathematical relationship that yields the capacitance estimate as a function of the known and well-controlled values for fundamental frequency of the ac signals and the resistance.

In addition, offset or mismatch errors may be reduced by using a correction technique, which helps compensate for unwanted parasitics. These unwanted parasitics may be due to the wiring that connects the DUT to the measurement circuitry, or where there may be non-negligible input capacitance at the input of the mixer.

In a further embodiment, the phase controllable signal generator and the peak detector are not needed. Instead, the two mixer inputs are coupled to the terminals of the resistor, respectively, so that the phase shift caused by the unknown DUT capacitance is obtained at the output of the low pass filter (e.g., as part the dc component of the mixer output). The estimate of the DUT capacitance may then be computed using essentially the same mathematical relationship given above, as a function of the same variables, namely resistance of the resistor, the fundamental frequency, and the phase shift (obtained from the dc component of the low pass filter output) as φₘₐₓ.

The above summary does not include an exhaustive list of all aspects of the present invention. It is contemplated that the invention includes all systems and methods that can be practiced from all suitable combinations of the various aspects summarized above, as well as those disclosed in the Detailed Description below and particularly pointed out in the claims filed with the application. Such combinations have particular advantages not specifically recited in the above summary.

### BRIEF DESCRIPTION OF THE DRAWINGS

The embodiments of the invention are illustrated by way of example and not by way of limitation in the figures of the accompanying drawings in which like references indicate similar elements. It should be noted that references to “an” or “one” embodiment of the invention in this disclosure are not necessarily to the same embodiment, and they mean at least one.

FIG. 1 is a circuit schematic of a capacitance measurement circuit.

FIG. 2 is a combined circuit schematic and block diagram of a capacitance measurement circuit as part of a display system.

FIG. 3 is a block diagram of some of the constituent components of a display system.

### DETAILED DESCRIPTION

Several embodiments of the invention with reference to the appended drawings are now explained. While numerous details are set forth, it is understood that some embodiments of the invention may be practiced without these details. In other instances, well-known circuits, structures, and techniques have not been shown in detail so as not to obscure the understanding of this description.

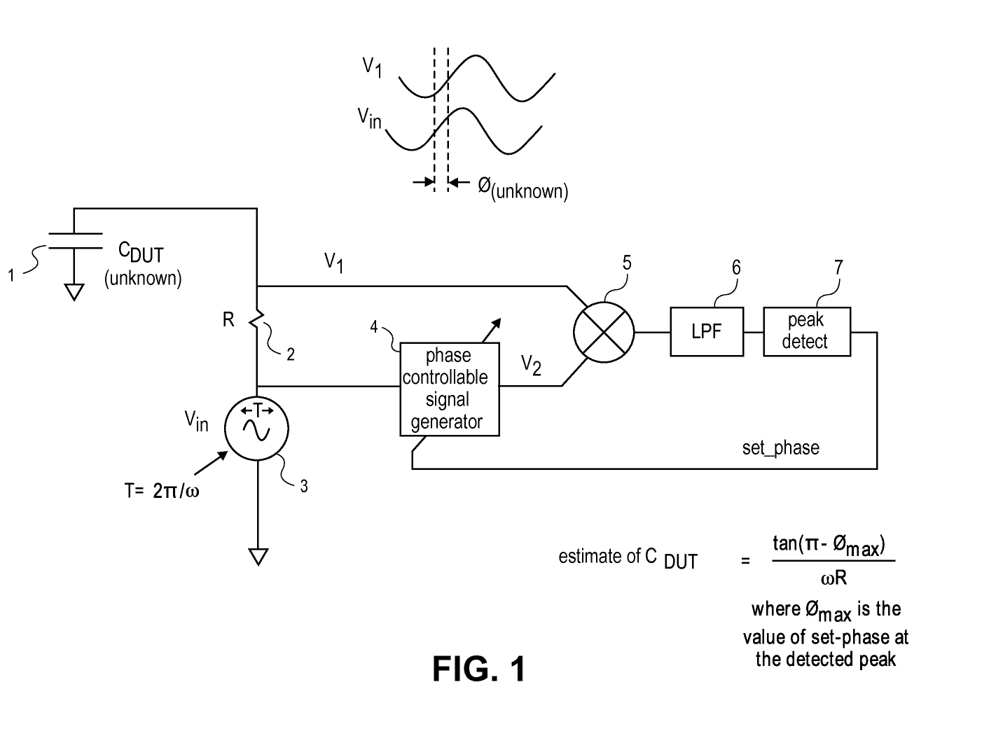

FIG. 1 is a circuit schematic of a capacitance measurement circuit that is coupled to a device under test (DUT) 1. The circuit may be used to obtain an estimate for, or a measure of, the usually unknown capacitance C_{DUT}. While the DUT 1 is depicted as a capacitor, in practice it may be an active device such as a transistor whose parasitic capacitance C_{gd} is being isolated and is therefore of interest. The DUT 1 may alternatively be a different passive or active device, e.g. a reverse biased diode. For purposes of measuring capacitance, two terminals of the DUT 1 are of interest, where one of them may be connected to a reference potential such as ground as shown, e.g. zero volts, and the other is used to inject a test signal into the DUT 1.

A resistor 2 having a known resistance R is coupled in series with the DUT 1 as shown. The resistor 2 may be a lumped passive element, or it may be an active circuit that includes one or more transistors or diodes although it should exhibit linear behavior during the measurement process described here. An ac signal source 3 produces an ac voltage signal Vᵢₙ having a known fundamental frequency ω (or period T=2π/ω), and is coupled to drive the resistor 2 at one terminal, to thereby produce a first ac voltage signal V₁ at another terminal of the resistor 2. In this case, the ac signal source 3 is also referenced to ground. The resistance 2 should be selected to be of the order of the impedance of C_{DUT} at ω, and preferably close to the impedance of C_{DUT} at ω. It should also not be too large, as compared to any parasitic resistances (not shown).

The ac signal source 3 may generate a pure sinusoid or single tone, but in practice this may not be practical in certain situations. As explained below, an alternative is to implement the ac signal source by passing a square wave signal (e.g., a binary clock signal) of the desired (and known) fundamental frequency, through a bandpass filter (e.g., an analog bandpass filter having a sufficiently narrow pass band) that will pass at least the fundamental frequency component (e.g., it may be narrow band centered at the fundamental frequency). Another approach is to use the square wave signal with a phase locked loop or an injection locking oscillator, to produce the desired narrow band, tone or single sinusoid signal.

In the embodiment shown, there is a phase controllable signal generator 4 that produces a second ac signal V₂ that may have the same known fundamental frequency ω, and whose phase is also known, e.g. relative to that of the ac signal source 3. This may be achieved for example by delaying Vᵢₙ and controlling the phase of V₂ at the output, according to a control input that receives set_phase. The control variable set_phase can be swept, under control of a peak detector 7 as described below. A phase locked loop or an injection locking oscillator may be used here to achieve a known phase relationship between the second ac signal V₂ and the ac signal source 3.

A product mixer 5 has a first input coupled to receive the first ac signal V₁ and a second input coupled to receive the second ac signal V₂. The mixer 5 may be a conventional analog mixer. The output of the mixer 5 is then fed through a low pass filter (LPF) 6 which may serve to extract what is essentially the dc component of the mixer output signal. The LPF 6 may also be an analog filter. Note that in another embodiment, the signal generator 4 is not needed such that an input of the mixer 5 may be directly connected to the Vᵢₙ side of the resistor 2.

In the embodiment shown, a peak detector 7 is provided that has an input coupled to an output of the low pass filter 6, and an output that provides set_phase, to control the phase shift introduced by the phase controllable signal generator 4 into the output signal V₂. The peak detector 7 may be a circuit that can indicate when it has detected a peak, e.g. a maximum positive value or a maximum negative value, at the output of the LPF 6, while sweeping set_phase, and can record the value of set_phase that produced the peak value at the LPF output. This value of set_phase is referred to here as φₘₐₓ. An aim here is to estimate φ_{unknown}, which is a phase difference between Vᵢₙ and V₁ that may have been caused by C_{DUT}, as φₘₐₓ. The underlying theory to validate this process is given below.

$${v}_{in} ( t ) = A sin ω t$$

$${v}_{1} ( t ) = \frac{A sin ( ωt - {tan}^{- 1} ( {ωRNC}_{gd} ) )}{\sqrt{1 + ( ω \cdot R \cdot {NC}_{gd} )}}$$

$${v}_{2} ( t ) = \frac{B}{2} + \frac{2 B}{π} {\sum }_{n = 1 , 3 , 5 …}^{∞} \frac{1}{π} sin ( n ω t - φ )$$

$${v}_{mixer} ( t ) = \frac{AB sin ( ω t - {tan}^{- 1} ( ω {RNC}_{gd} ) )}{2 \sqrt{1 + ( w \cdot R \cdot {NC}_{gd} )}} + \frac{2 AB {\sum }_{n = 1 , 3 , 5 …}^{∞} \frac{1}{n} sin ( πω t - φ ) sin ( ω t - {tan}^{- 1} ( ω {RNC}_{gd} ) )}{π \sqrt{1 + ( w \cdot R \cdot {NC}_{gd} )}}$$

$${v}_{LPF} ( t ) = \frac{AB cos ( - φ + {tan}^{- 1} ( ω {RNC}_{gd} ) )}{π \sqrt{1 + ( w \cdot R \cdot {NC}_{gd} )}}$$

$$max ( {v}_{LPF} ) = \frac{AB}{π \sqrt{1 + ( w \cdot R \cdot {NC}_{gd} )}} when \{ φ - {tan}^{- 1} ( ω {RNC}_{gd} ) = 0 \}$$

$${φ}_{max} = {tan}^{- 1} ( ω {RNC}_{gd} ) -> {C}_{gd} = \frac{tan ( {φ}_{max} )}{ω RN}$$

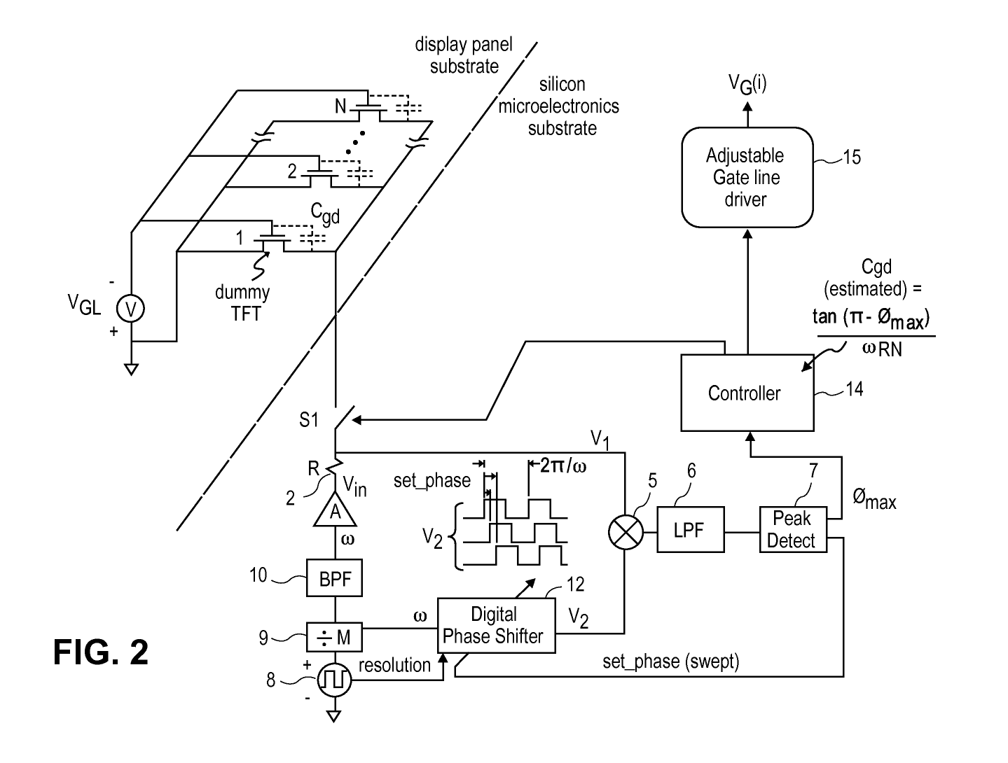

As seen above, the derivation refers to the particular case where C_{DUT}=NCgd (described below in connection with FIG. 2), but otherwise the derivation is generic. It should thus be appreciated that an estimate of C_{DUT} can be obtained readily, once φₘₐₓ has been found, based on the maximum value of the dc component of the mixer output signal.

In the embodiment of FIG. 1, though not shown, there is a means for using a value from the output of the peak detector 7 to obtain a measure of the unknown capacitance C_{DUT}. In one case, this means includes a look up table having a list of previously determined phase values (φₘₐₓ values) and their associated estimate C_{DUT} values, computed using the formula shown above (as well as in FIG. 1). A range of these discrete φₘₐₓ values may be from zero to a radians, and their step size or resolution should be selected to provide sufficient accuracy in the estimate value of C_{DUT}. As an alternative to the lookup table, the means for obtaining a measure of C_{DUT} can be a programmed controller that computes the capacitance value using the given formula, as a function of a) a frequency value (e.g., representative of the known ω), b) a resistance value (e.g., representative of the known R), and of course c) the phase value φₘₐₓ from the output of the peak detector 7.

In another embodiment, neither the peak detector 7 nor the means for computing a capacitance value (estimate of C_{DUT}), which is a programmed controller or a lookup table, actually records φₘₐₓ. Instead, the formula given above for V_{lpf} is used, when the maximum value of the LPF 6 output has been found, to compute C_{DUT} without using φₘₐₓ. In that case however, the values A and B, which are amplitudes of the signals V₁ and V₂, respectively, need to be known or measured, in order to use the formula for V_{lpf}. This however may introduce measurement errors that would be absent from the φₘₐₓ approach.

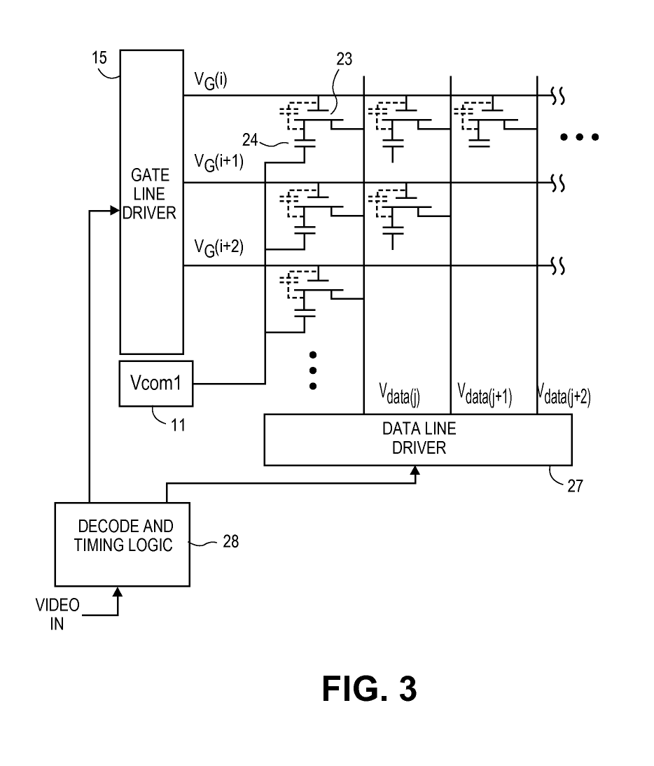

Turning now to FIG. 2, a combined circuit schematic and block diagram of the capacitance measurement circuit as part of a display system is shown. However, before describing this particular measurement circuit, the display system of which it is a part is briefly described in connection with FIG. 3. There, a block diagram of certain parts of the display system is shown. The display system has an array of display elements or pixels that form an image viewable region of a screen, for instance. Each individual pixel may include a transistor referred to here as a thin film transistor (TFT) 23, that may be operated as a switch, to selectively apply (turn on and turn off) a data line signal that is received on one of its carrier electrodes (here, the source electrode), on to a plate of a capacitor 24 that is connected to its other carrier electrode (drain electrode). Note also the depiction of a capacitor C_{gd} in dotted lines, for each TFT 23.

In this case, each TFT 23 of the respective pixel has its control electrode directly connected to a respective gate line that is driven by a voltage source V_{G}, and these voltage sources can be found within gate line driver circuitry 15. The data line signals are provided by voltage sources V_{data} that are found within data line driver circuitry 27. The data line driver circuitry 27, also called the source driver circuitry, receives control or timing signals and digital pixel signals from decode and timing logic 28. The latter translates incoming digital video pixel values (for example, red, green and blue digital pixel values) into analog data signals with appropriate timing, that are driven onto the data lines. The data line driver 27 performs the needed voltage level shifting, for example, to produce a data line voltage having not just the needed fan out or current capability, but also the desired amplitude or signal swing with the appropriate gray level voltage.

The capacitor 24 may include a liquid crystal capacitor that is formed between a pixel plate electrode and a common plate or electrode, where the latter is, in this example, directly connected to a number of other pixels in the same column, by virtue of a common voltage line that runs vertically as shown (similar to the data lines). A further capacitor (not shown), referred to as a storage capacitor, may be added to the pixel electrode, to increase the analog storage at that node. Other circuit arrangements for a storage circuit at the pixel electrode are possible.

In FIG. 3, the pixels in column j are all connected to the same common voltage line that terminates at a common voltage generation source circuit 11, which contains a variable voltage source that produces and maintains a voltage Vcom1 on the common voltage line.

Returning to FIG. 2, here the DUT 1 is a set of N dummy TFTs that are connected in parallel as shown. Each of the dummy TFTs may be a replicate of a real device, e.g. a real pixel TFT 23 as seen in FIG. 3, whose unknown gate-drain capacitance C_{gd} is to be estimated. Both the real TFTs 23 and the dummy TFTs (FIG. 2) may be formed on the same display panel substrate, e.g. a transparent glass or plastic substrate, although the dummy TFTs need not be in the active display element array region where the real pixel TFTs 23 are formed. There are N dummy TFTs, and this number should be selected in view of the accuracy available from the measurement circuit, and how small is the capacitance of each individual C_{gd} (it may be too small to measure individually). It is desirable however to keep N as small as possible, to reduce chip real estate or area overhead consumed by the measurement circuit.

A bias circuit that produces a gate bias voltage V_{GL} may also be provided, to bias each of the dummy TFTs into its cutoff state, during the measurement process. In the case of an N-channel enhancement TFT, V_{GL} may be a negative dc voltage as depicted in FIG. 2.

A controller 14 may also be provided, to modify an adjustable gate line driver 15, in accordance with the estimated measure of C_{gd}. The gate line driver 15 is an example of a driver circuit in the display system that is actually used to drive a real TFT of the system, and whose drive strength is adjustable so as to achieve consistent turn-off performance for the real TFT. As an alternative to a gate line driver 15, a data line driver 27 (see FIG. 3) can be made adjustable as a function of the estimated C_{gd}, to maintain consistent performance by the real TFTs 23.

Still referring to FIG. 2, the measurement circuit shown here has a generally similar form to the one in FIG. 1, in that it also includes the resistor 2, mixer 5, LPF 6 and peak detector 7. The ac signals V₁ and V₂ are however generated in a particular way, as follows. For the ac signal source 3 (FIG. 1) that produces Vᵢₙ is implemented using a square wave generator 8 having an output that feeds a bandpass filter 10 through a frequency divider 9. The square wave generator 8 has a fairly high fundamental frequency that is divided down to the desired ω (by selecting the integer M of the divider 9). The square wave at ω is then band pass filtered (at a passband that may be centered at ω), to result in essentially a narrow band tone at ω. This way of generating essentially a single tone or single sinusoid signal is particularly desirable when implementing the circuitry of the square wave generator 8, the divider 9 and the BPF 10 using a standard digital microelectronic fabrication process, e.g. CMOS processes. An optional buffer amplifier A may be added to the output of the BPF 10, to drive the resistance R and the series coupled DUT, which are the N parallel connected dummy TFTs.

The measurement circuit in FIG. 2 also shows a further embodiment of the invention, namely one where the phase controllable signal generator 4 (FIG. 1) is implemented using a digital phase shifter 12, in order to produce the ac signal V₂. The digital phase shifter 12 may provide a discrete set of phase states or shifts, between zero and a radians for example, that may be controlled by several “phase bits.” For example, a K bit phase shifter could have about 2^{K} different phase states that could be spread evenly between zero to π. The resolution of each step in phase state may be defined by a readily available, relatively high-frequency square wave, e.g. the one produced by the square wave generator 8. The effect of phase shifting an input square wave signal, e.g., having a period T=2π/ω, which signal may be obtained from the divider 9, is shown by the three different waveforms for the output signal V₂. The “current” phase state is selected as per the set_phase variable, which is being swept by the peak detector 7.

Still referring to FIG. 2, yet another embodiment of the invention is shown here, namely that of a correction capability, which serves to remove the effect of parasitic capacitance that may be present at the circuit node for V₁. This is enabled through the use of a switch circuit S1 that is coupled to the resistor 2 so as to be in series between the resistor 2 and the DUT 1 (see FIG. 1). The switch circuit S1 has at least two states. In its closed state, the ac signal source Vᵢₙ drives the DUT and the mixer input. In the open state however, Vin does not drive the DUT but instead only drives the mixer input. In each state of the switch S1, the measurement circuit is operated so as to sweep set_phase until a peak is detected at the output of the LPF 6 and an associated estimate of C_{DUT} or C_{gd} is obtained (as was described above). The estimate obtained with the switch closed reflects the true DUT capacitance plus a contribution from undesired parasitic capacitances (e.g., interconnect parasitics and input capacitance of the mixer 5), whereas the estimate obtained with the switch open reflects only the contribution from the undesired parasitic capacitances—the difference between these two estimates should be a more accurate estimate of the true DUT capacitance.

The controller 14 may be used to conduct the correction process, as follows: configure the switch circuit S1 into the first state and determine a first capacitance value using an output of the peak detector 7; configure S1 into the second state and determine a second capacitance value, again using the output of the peak detector 7; and use the determined first and second values to compute a corrected estimate of the capacitance of the DUT, e.g. take the difference between the first and second capacitance values. The controller 14 may be implemented using, for example, a state machine, or it may be a programmed processor with a program counter.

While certain embodiments have been described and shown in the accompanying drawings, it is to be understood that such embodiments are merely illustrative of and not restrictive on the broad invention, and that the invention is not limited to the specific constructions and arrangements shown and described, since various other modifications may occur to those of ordinary skill in the art. For example, while FIG. 2 depicts the gate line driver 15 on the silicon microelectronics side, as opposed to the display panel substrate side, in practice the gate line driver 15 is often formed on the display panel substrate (e.g., glass) rather than in a separate semiconductor display driver IC. That technology is also referred to as gate driver on array (GOA). The description is thus to be regarded as illustrative instead of limiting.

What is claimed is:

1. A capacitance measurement circuit comprising:
a resistor having a known resistance, to be coupled in series with a device under test (DUT) having an unknown capacitance;
an ac signal source having a known fundamental frequency and being coupled to drive the resistor to thereby produce a first ac signal;
a phase controllable signal generator to produce a second ac signal;
a mixer having a first input coupled to receive the first ac signal and a second input coupled to receive the second ac signal;
a low pass filter having an input coupled to an output of the mixer; and
a peak detector having an input coupled to an output of the low pass filter and an output coupled to control the phase controllable signal generator.

2. The capacitance measurement circuit of claim 1 further comprising
means for using a value from the output of the peak detector to obtain a measure of the unknown capacitance of the DUT.

3. The capacitance measurement circuit of claim 2 wherein said means comprises a look up table having a list of previously determined phase values and their associated capacitance values.

4. The capacitance measurement circuit of claim 2 wherein said means comprises means for computing a capacitance value as a function of a) a frequency value, b) a resistance value, and c) a phase value from the output of the peak detector.

5. The capacitance measurement circuit of claim 4 wherein the frequency value is representative of the known frequency of the ac signal source, and the resistance value is representative of the known resistance of the resistor.

6. The capacitance measurement circuit of claim 2 wherein said means comprises means for computing a capacitance value as a function of a) a frequency value, b) a resistance value, and c) maximum value of the output of the low pass filter as detected by the peak detector.

7. The capacitance measurement circuit of any one of claim 1 wherein the ac signal source comprises a square wave generator having an output that feeds a bandpass filter through a frequency divider, and the phase controllable signal generator comprises a digital phase shifter having a) a first control input coupled to an output of the square wave generator, b) a second control input coupled to the output of the peak detector, and c) a signal input coupled to an output of the frequency divider.

8. The capacitance measurement circuit of any one of claim 1 further comprising a switch circuit coupled to the resistor, the switch circuit having first and second states, wherein the ac signal source can drive the to-be-coupled DUT in the first state but not in the second state, and wherein in both the first and second states the first input of the mixer remains coupled to receive the first ac signal.

9. The capacitance measurement circuit of claim 8 further comprising a controller that is to configure the switch circuit into a) the first state and determine a first value using an output of the peak detector, and b) the second state and determine a second value using said output of the peak detector, and use the determined first and second values to compute an estimate of the capacitance of the DUT.

10. An electronic system having a display panel, comprising:
a display panel having a real device;
an adjustable driver coupled to drive the real device;
a device under test (DUT) having a plurality of dummy devices connected in parallel, each of the dummy devices being a replicate of the real device; and
a measurement circuit having a resistor with a known resistance, coupled in series with the DUT, an ac signal source having a known fundamental frequency and being coupled to drive the resistor to thereby produce a first ac signal, a signal generator to produce a second ac signal having a known fundamental frequency and phase relative to that of the ac signal source, a mixer having a first input coupled to receive the first ac signal and a second input coupled to receive the second ac signal, a low pass filter having an input coupled to an output of the mixer, and means for using a value from an output of the low pass filter to obtain a measure of capacitance of the DUT; and
a controller coupled to modify the adjustable driver in accordance with the obtained measure of capacitance.

11. The system of claim 10 wherein the real device is a pixel TFT, and the adjustable driver is a gate line driver.

12. The system of any one of claims 11 further comprising a bias circuit coupled to bias each the plurality of dummy devices into its cutoff state while the ac signal source drives the resistor.

13. The system of any one of claim 10 wherein the display panel comprises a substantially transparent glass or plastic substrate on which the real device and the DUT are formed.

14. The system of claim 13 wherein the measurement circuit is formed in a separate display driver integrated circuit, on a different substrate than the display panel substrate.

15. The system of any one of claim 10 wherein the ac signal source comprises a square wave generator having an output that feeds one of a) a bandpass filter through a frequency divider, b) a phase locked loop and c) an injection locked oscillator.

16. The system of claim 15 further comprising a peak detector coupled to the output of the low pass filter,
and wherein the signal generator comprises a digital phase shifter having a) a first control input coupled to an output of the square wave generator, b) a second control input coupled to the output of the peak detector, and c) a signal input coupled to an output of the frequency divider.

17. A method for measuring capacitance, comprising:
a) driving an ac signal through a circuit loop that contains a resistor coupled in series with a device under test (DUT);
b) while driving the ac signal, detecting the phase shift between voltages at two different points along the circuit loop; and
c) obtaining an estimate of the DUT's capacitance using the detected phase shift.

18. The method of claim 17 wherein obtaining the estimate of the DUT capacitance comprises computing the estimate using a formula that is a function of a) fundamental frequency of the ac signal, b) resistance of the resistor, and c) the detected phase shift.

19. The method of claim 17 further comprising adjusting a display driver circuit based on the estimate of the DUT's capacitance.

20. The method of claim 17 wherein a)-c) are performed twice, once when a switch circuit that is in series between the resistor and the DUT is closed, and once when the switch circuit is open, to thereby obtain two estimates of the DUT's capacitance, the method further comprising obtaining a corrected estimate of the DUT's capacitance using the two estimates.
